(19) United States
(12) Patent Application Publication
(10) Pub. No.: US 2025/0359013 A1
(43) Pub. Date: Nov. 20, 2025

(54) THREE-DIMENSIONAL STACKED DYNAMIC RANDOM-ACCESS MEMORY AND METHOD FOR MANUFACTURING THE SAME

(71) Applicant: INSTITUTE OF MICROELECTRONICS, CHINESE ACADEMY OF SCIENCES, Beijing (CN)

(72) Inventors: Huaxiang Yin, Beijing (CN); Qingzhu Zhang, Beijing (CN); Jiaxin Yao, Beijing (CN); Gaobo Xu, Beijing (CN)

(21) Appl. No.: 18/727,971

(22) PCT Filed: Sep. 15, 2023
(86) PCT No.: PCT/CN2023/118988

§ 371 Date: Jul. 10, 2024

(30) Foreign Application Priority Data
Aug. 24, 2023 (CN) 202311075690.2

(51) Int. Cl. H10B 12/00

(52) U.S. Cl. CPC H10B 12/30; H10B 12/05

(57) ABSTRACT

A 3D stacked DRAM and a method for manufacturing the same. The 3D stacked DRAM comprises: a substrate, a source, a drain, a storage structure, a common source electrode, drain electrodes, and a gate. The storage structure comprises a stack of nanosheets extending from the source to the drain. The common source electrode is in contact with each nanosheet and is grounded. A portion of the nanosheets extending into the drain is shaped as a stair structure. Each drain electrode runs into the drain, is in contact with a respective nanosheet in the stair structure and is connected to a bit line. The gate surrounds each nanosheet and is connected to a word line.

This application claims priority to Chinese Patent Application No. 202311075690.2, titled “THREE-DIMENSIONAL STACKED DYNAMIC RANDOM-ACCESS MEMORY AND METHOD FOR MANUFACTURING THE SAME”, filed on Aug. 24, 2023 with the China National Intellectual Property Administration, which is incorporated herein by reference in its entirety.

### FIELD

The present disclosure relates to the technical field of semiconductor, and in particular to a three-dimensional stacked dynamic random-access memory and a method for manufacturing the same.

### BACKGROUND

Semiconductor memory devices may be volatile or non-volatile. Although data stored in the volatile memory devices may be lost when powering off, these memory devices can perform reading and writing at high speed, and thus are widely applied as media for temporary data storage.

The volatile semiconductor memory devices include dynamic random-access memories (DRAMs). As shown in FIG. 1, DRAM architecture mainly comprises an array of tremendous identical memory cells and a peripheral reading-writing circuit. The array of memory cells is a core which determines integration density and manufacturing costs. Conventional memory cells are 1T1C units. “1T” represents that each memory cell comprises one memory access transistor, which shall have high performances and an extremely low leakage current. “1C” represents that each memory cell comprises one storage capacitor, which shall store many charges within a space having a small orthogonal projection. When performing reading or writing on a certain memory cell in the array, a word line (WL) is utilized to activate a voltage on a row comprising such memory cell, and a bit line (BL) is utilized to read a voltage for/on a column comprising such memory cell. Thereby, data to be read or written for each memory cell can be determined through a combination the WL and the BL. The BL may be called a digit line. For the sake of analogy, the WL may be regarded as a tap, the memory access transistor may be regarded as a switch, the BL may be regarded as a pipe, and the storage capacitor may be regarded as a bucket. When the tap is switched on, water is transported via the pipe and stored in the bucket to implement memory.

Continuous miniaturization of integrated circuits keeps putting new requirements on the integration density of DRAM and a structure of each memory cell.

### SUMMARY

In view of at least the above, a three-dimensional (3D) stacked dynamic random-access memory (DRAM) and a method for manufacturing the 3D stacked DRAM are provided according to embodiments of the present disclosure. A size of each memory cell is reduced, integration density of the DRAMs is increased, and hence high-density data storage is achieved.

A 3D stacked DRAM is provided according to an embodiment of the present disclosure. The 3D stacked DRAM comprises: a substrate; a source, a drain and a storage structure, which are disposed on a side of the substrate, where the storage structure is located between the source and the drain and comprises a stack of nanosheets, each of the nanosheets extends from the source to the drain, and a portion of the nanosheets which extends into the drain is shaped into a stair structure; a common source electrode running through the source, where the common source electrode is in contact with each of the nanosheets, and is grounded; drain electrodes running into the drain, where each of the drain electrodes is in contact with a respective one of the nanosheets that forms a step of the stair structure, and the drain electrodes are configured to connect bit lines for the 3D stacked DRAM; and a gate surrounding each of the nanosheets, where the gate is configured to connect one or more word lines for the 3D stacked DRAM.

In an embodiment, the storage structure comprises a first storage structure and a second storage structure, the gate comprises a first gate and a second gate, and the one or more word lines comprise a first word line and a second word line. The first gate and the second gate are isolated by a dielectric material, and the first gate surrounds each of the nanosheets in the first storage structure and is configured to connect the first word line. The second gate surrounds each of the nanosheets in the second storage structure and is configured to connect the second word line.

In an embodiment, lengths of the nanosheets gradually increase in a direction pointing from the storage structure to the substrate.

In an embodiment, the source and the drain are asymmetric to each other in structure.

In an embodiment, a quantity of the bit lines is identical to a quantity of the nanosheets.

A method for manufacturing a 3D stacked DRAM is provided according to an embodiment of the present disclosure. The method comprises: providing a substrate, where a first stacked structure in which first semiconductor layers and second semiconductor layers are alternately arranged is formed on a side of a substrate; oxidizing the first semiconductor layers to obtain a second stacked structure in which isolation layers and the second semiconductor layers are alternately arranged; shaping a side portion of the second stacked structure through photolithography into a stair structure; doping two side portions of the second stacked structure to form a source and a drain, respectively, where the drain comprises the stair structure, and the second stacked structure between the source and the drain serves as a channel structure; replacing the isolation layers in the channel structure with a gate, where the gate surrounds each of the second semiconductor layers, the stacked second semiconductor layers serve as a storage structure, and the gate is configured to connect one or more word lines for the 3D stacked DRAM; forming a common source electrode which runs through the source, and forming drain electrodes which run into the drain, where the common source electrode is in contact with each of the second semiconductor layers and is grounded, each drain electrode is in contact with a respective one of the second semiconductor layers in the stair structure, and the drain electrodes are configured to connect bit lines for the 3D stacked DRAM.

In an embodiment, oxidizing the first semiconductor layers to obtain the second stacked structure comprises: oxidizing the first semiconductor layers through selective oxidation.

In an embodiment, shaping the side portion of the second stacked structure through the photolithography into the stair structure comprises: forming a photoresist layer on the second stacked structure; repeating: trimming the photoresist layer, and etching the second stacked structure with the trimmed photoresist layer as a mask to form one step in the stair structure, where a depth of the etching is equal to a thickness of a period of the second stacked structure, to form the stair structure, where dimensions of steps of the stair structure along a dimension pointing from the source to the drain gradually increase; and removing the photoresist layer.

In an embodiment, before oxidizing the first semiconductor layers to obtain the second stacked structure, the method further comprises: etching the first stacked structure and the substrate to form a first fin and a second fin, where the storage structure comprises a first storage structure and a second storage structure, the gate comprises a first gate and a second gate, and the word line comprises a first word line and a second word line; the method further comprises: etching the gate along a direction perpendicular to the substrate and perpendicular to a line connecting the source and the drain to form the first gate and the second gate, where the first gate surrounds each of the second semiconductor layers in the first storage structure, the first gate is configured to connect the first word line, the second gate surrounds each of the second semiconductor layers in the second storage structure, the second gate is configured to connect the second word line, the first storage structure is fabricated from the first fin, and the second storage structure is fabricated from the second fin; and filling a gap between the first gate and the second gate with a dielectric material for isolation.

In an embodiment, replacing the isolation layers in the channel structure with the gate comprises: removing the isolation layers in the channel structure to form multiple gaps among the second semiconductor layers; and filling the multiple gaps with the gate.

Herein the 3D stacked DRAM comprising the substrate, the source, the drain, the storage structure, the common source electrode, the drain electrodes, and the gate is provided. The source, the drain, and the storage structure are disposed on the side of the substrate, and the storage structure is located between the source and the drain. The storage structure comprises the stack of nanosheets, and each nanosheet extends from the source to the drain. That is, each nanosheet may serve as a memory cell for data storage. The common source electrode runs through the source to contact each nanosheet, and the common source electrode is grounded to connect each nanosheet to ground electrically, i.e., to connect the memory cell and the ground. The portion of the nanosheets that is located at the drain is shaped into the stair structure. Each drain electrode runs into the drain to connect the respective nanosheet in the stair structure, and the drain electrodes are configured to connect the bit lines for the 3D stacked DRAM, such that the nanosheets and the bit lines are electrically connected. The gate surrounds each nanosheet and is configured to connect the word line(s) for the 3D stacked DRAM, such that the nanosheets and the word line(s) are electrically connected. That is, each nanosheet is connected to the word line(s) via the gate, is grounded via the source, and is connected to the corresponding bit line via the drain to achieve data storage. Such architecture in combination with vertical stacking of memory cells improves integration density of memory cells greatly. Thereby, an array of three-dimensionally stacked 1T memory cells is formed through the vertical stacking of memory cells, gate-all-around structure of each memory cell, and the stair structure for connecting the drain in each memory cell. High-density data storage can be achieved.

### BRIEF DESCRIPTION OF THE DRAWINGS

Hereinafter drawings to be applied in embodiments of the present disclosure are briefly described to clarify illustration of technical solutions according to embodiments of the present disclosure. Apparently, the drawings in the following descriptions are only some embodiments of the present disclosure, and other drawings may be obtained by those skilled in the art based on the provided drawings without exerting creative effort.

FIG. 1 is a schematic structural diagram of an array of memory cells in a dynamic random-access memory (DRAM).

FIG. 2 is a schematic stereoscopic view of a three-dimensional (3D) stacked DRAM according to an embodiment of the present disclosure.

FIGS. 3 and 4 are schematic structural diagrams of cross sections along different directions of a semiconductor device as shown in FIG. 2 according to an embodiment of the present disclosure.

FIG. 5A is a schematic diagram of a theoretical concept of data storage of a 3D stacked DRAM according to an embodiment of the present disclosure.

FIG. 5B is a schematic flow chart of a method for manufacturing a 3D stacked DRAM according to an embodiment of the present disclosure.

FIGS. 6 to 20 are schematic diagrams of structures during a method for manufacturing a 3D stacked DRAM according to an embodiment of the present disclosure.

### DETAILED DESCRIPTION OF EMBODIMENTS

Hereinafter specific implementations of the present disclosure are described in detail in conjunction with the drawings to clarify and elucidate objectives, features, and advantages of the present disclosure.

Various details are set forth in following description for full understanding of the present disclosure. The present disclosure may be implemented in an embodiment different from those described herein. Those skilled in the art may make deduction without violating a concept of the present disclosure, and hence the present disclosure is not limited to embodiments disclosed as follows.

The present disclosure is described in detail in conjunction with schematic diagrams. In order to facilitate illustrating embodiments, a cross-sectional diagram of a device structure may not be enlarged to scale in all parts, and the schematic diagrams are only exemplary and shall not be construed as limitations on a protection scope of the present disclosure. In practice, a structure shall be manufactured with three spatial dimensions such as a length, a width, and a depth.

Semiconductor memory devices may be volatile or non-volatile. Although data stored in the volatile memory devices may be lost when powering off, these memory devices can perform reading and writing at high speed, and thus are widely applied as media for temporary data storage.

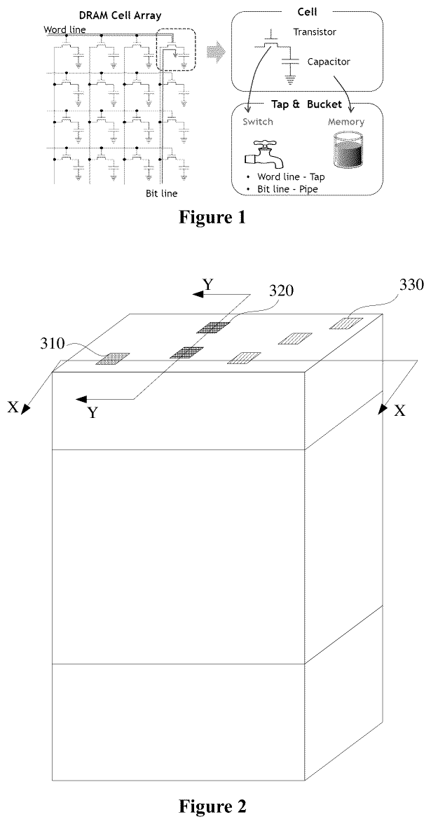

The volatile semiconductor memory devices include dynamic random-access memories (DRAMs). As shown in FIG. 1, DRAM architecture mainly comprises an array of tremendous identical memory cells and a peripheral reading-writing circuit. The array of memory cells is a core which determines integration density and manufacturing costs. Conventional memory cells are 1T1C units. “1T” represents that each memory cell comprises one memory access transistor, which shall have high performances and an extremely low leakage current. “1C” represents that each memory cell comprises one storage capacitor, which shall store many charges within a space having a small orthogonal projection. When performing reading or writing on a certain memory cell in the array, a word line (WL) is utilized to activate a voltage on a row comprising such memory cell, and a bit line (BL) is utilized to read a voltage for/on a column comprising such memory cell. Thereby, data to be read or written for each memory cell can be determined through a combination the WL and the BL. The BL may be called a digit line. For the sake of analogy, the WL may be regarded as a tap, the memory access transistor may be regarded as a switch, the BL may be regarded as a pipe, and the storage capacitor may be regarded as a bucket. When the tap is switched on, water is transported via the pipe and stored in the bucket to implement memory.

Conventional DRAMs have developed from planar structures to three-dimensional (3D) structures and even to 3D stacked structures with continuous miniaturization of integrated circuits. An example of the 3D structure is vertical channel array transistors (VCATs), and an example of the 3D stacked structure is a structure comprising stacked ferroelectric field effect transistor (FeFET) memory cells.

That is, there new requirements on integration density of DRAM and a structure of each memory cell.

In view of at least the above, a 3D stacked DRAM is provided according to embodiments of the present disclosure. The 3D stacked DRAM comprises a substrate, a source, a drain, a storage structure, a common source electrode, drain electrodes, and a gate. The source, the drain, and the storage structure are disposed on a side of the substrate, and the storage structure is located between the source and the drain. The storage structure comprises a stack of nanosheets, and each nanosheet extends from the source to the drain. That is, each nanosheet may serve as a memory cell for data storage. The common source electrode runs through the source to contact each nanosheet, and the common source electrode is grounded to connect each nanosheet to ground electrically, i.e., to connect the memory cell and the ground. A portion of the nanosheets that is located at the drain is shaped into a stair structure. Each drain electrode runs into the drain to connect a respective nanosheet in the stair structure, and the drain electrodes are configured to connect bit lines for the 3D stacked DRAM, such that the nanosheets and the bit lines are electrically connected. The gate surrounds each nanosheet and is configured to connect word line(s) for the 3D stacked DRAM, such that the nanosheets and the word line(s) are electrically connected. That is, each nanosheet is connected to the word line(s) via the gate, is grounded via the source, and is connected to the corresponding bit line via the drain to achieve data storage. Such architecture in combination with vertical stacking of memory cells improves integration density of memory cells greatly. Thereby, an array of three-dimensionally stacked 1T memory cells is formed through the vertical stacking of memory cells, gate-all-around structure of each memory cell, and the stair structure for connecting the drain in each memory cell. High-density data storage can be achieved.

Hereinafter specific embodiments are described in detail in conjunction with the drawings for better understanding of the technical solutions and technical effects of the present disclosure.

Reference is made to FIG. 2, which is a schematic stereoscopic view of a 3D stacked DRAM according to an embodiment of the present disclosure.

The 3D stacked DRAM comprises a substrate 110, a source 131, a drain 132, a storage structure, a common source electrode 210, multiple drain electrodes 220, and a gate 160.

In an embodiment, the substrate 110 may be a semiconductor substrate, such as a bulk silicon substrate. The substrate 110 may be doped to obtain a p-doped semiconductor substrate or an n-doped semiconductor substrate, such as a p-doped silicon substrate or an n-doped silicon substrate.

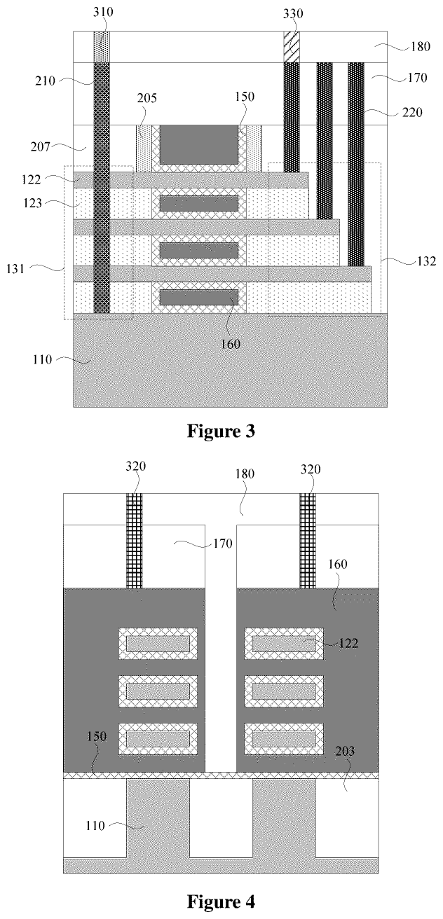

In an embodiment, the source 131, the drain 132, and the storage structure are disposed on a side of the substrate 110. The storage structure comprises a stack of nanosheets between the source 131 and the drain 132. Each nanosheet extends from the source 131 to the drain 132, so that each nanosheet may serve as a memory cell for data storage. The multiple nanosheets are vertically stacked to form the 3D stacked DRAM having multiple memory cells which are highly integrated. The storage structure may be obtained through removing isolation layers 123 in a stacked structure comprising the isolation layers 123 and second semiconductor layers 122 that are alternatively arranged. That is, the nanosheets in the storage structure origin from the second semiconductor layers 122 in the stacked structure. Reference is made to FIGS. 3 and 4. FIG. 3 is a schematic structural diagram of a cross section along direction XX of a semiconductor device as shown in FIG. 2 according to an embodiment of the present disclosure. FIG. 3 is a schematic structural diagram of another cross section along direction YY of a semiconductor device as shown in FIG. 2 according to an embodiment of the present disclosure. Direction YY refers to a direction parallel with an extension direction of the gate, and the XX direction refers to direction parallel with an extension direction of fin(s).

Herein gap(s) between adjacent nanosheets in the storage structure are filled with the gate 160. That is, the gate 160 surrounds each nanosheet to form and a gate-all-around structure. The gate 160 may be configured to connect to a word line (WL) for the 3D stacked DRAM, such that a switch of each memory cell in the 3D stacked DRAM is controlled through the word line.

Herein in the 3D stacked DRAM, the common source electrode 210 runs into the source 131 to achieve electrical connection between multiple memory cells and a ground potential (GP). The common source electrode 210 is in contact with each nanosheet, and the common source electrode 210 is connected to the GP, that is, each memory cell is grounded.

Herein the portion of the nanosheets, which extends into the drain 132, is shaped into the stair structure, and the multiple drain electrodes 220 run into the drain 132. That is, each drain electrode 220 runs into the drain 132 to contact a respective nanosheet in the stair structure. The drain electrodes 220 are configured to connect the bit lines (BLs), such that each memory cell is connected to a bit line for the 3D stacked DRAM. That is, different memory cells are electrically led out from different depths in the drain 132 to connect the bit lines.

Hence, the vertical stacking of memory cells may utilize conventional techniques of nanosheet gate-all-round field-effect transistor (GAAFET), which can break through the 3 nm limitation to fabricate smaller and more integrated semiconductor devices. The nanosheet is connected to the word line via the gate, is connected to the ground potential via the source, and is connected to the bit line via the drain to achieve data storage. Such architecture in combination with vertical stacking of memory cells improves integration density of memory cells greatly. Thereby, an array of three-dimensionally stacked 1T memory cells is formed through the vertical stacking of memory cells, gate-all-around structure of each memory cell, and the stair structure for connecting the drain in each memory cell. A quantity of memory cells in the array formed on a basis of the Nanosheet GAAFET techniques is determined by a quantity of the vertically stacked nanosheets. More nanosheets lead to more memory cells. Thus, integration density can be greatly improved to achieve high-density data storage, and manufacturing costs can be reduced due to the utilization of conventional techniques.

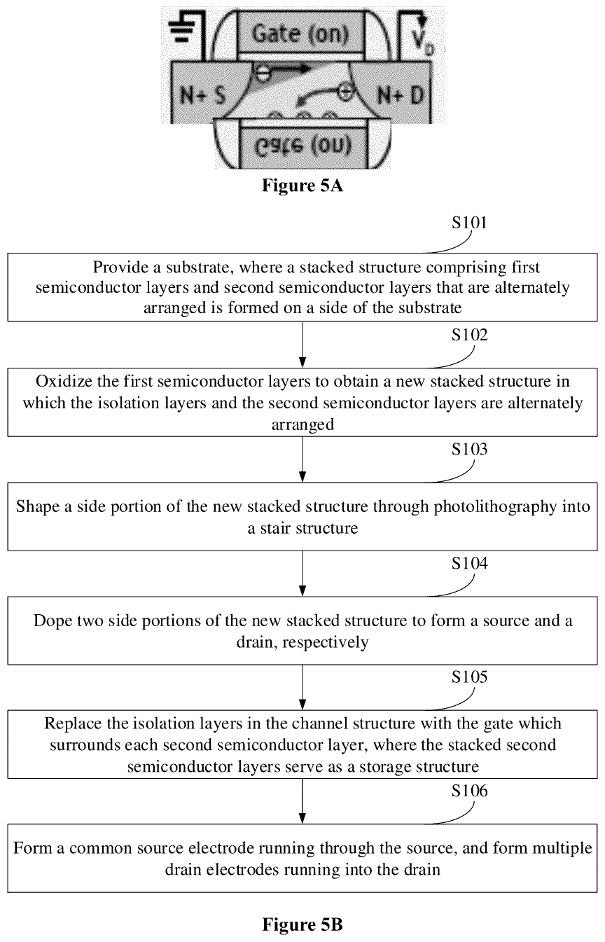

Reference is made to FIG. 5A. S represents the source 131 connected to the ground potential, D represents the drain 132 connected to the bit line, a voltage on the bit line is V_{D}, and Gate represents the gate 160. Excessive charges of high density can be stored in the semiconductor device through a floating-body channel that is formed by the vertically stacked nanosheets. That is, an effect of channel floating-charge storage is implemented, high performances of 1T DRAM cells are achieved.

Herein the portion of the nanosheets extending into the drain 132 is shaped into the stair structure, such that in the storage structure, each nanosheet may be connected to a respective drain electrode 220. In an embodiment, lengths of the nanosheets gradually increase in a direction pointing from the storage structure toward the substrate 110. The length refers to a dimension along a direction parallel to the extension direction of the fin(s). That is, the closer a nanosheet is to the substrate 110, the greater the length of the nanosheet is, such that the nanosheets having different lengths form the stair structure. The stair structure facilitates forming connections to different bit lines in a subsequent step, which connects each memory cell to the corresponding bit line.

Herein the common source electrode 210 connected to each nanosheet is disposed in the source 131, and the stair structure of nanosheets is formed in the drain 132 for respective connections with different drain electrodes 220. That is, the electrode 131 and the drain 132 are asymmetric to each other in such architecture.

In an embodiment, the vertically stacked nanosheets in the storage structure are isolated from each other via the gate 160 and a high-k dielectric layer 150 that are stacked, or via a polysilicon layer and an oxide layer that are stacked. In the source 131 and the drain 132, the multiple nanosheets are also isolated from each other. In an embodiment, first semiconductor layers 121 may be oxidized to form the isolation layers 123, and the isolation layers 123 are configured to isolate the multiple nanosheets in the source 131 and the drain 132. A material of the first semiconductor layers 121 may be silicon germanium. A material of the second semiconductor layers 122, i.e., a material of the nanosheets, may be silicon.

In an embodiment, the high-k dielectric layer 150 is disposed between the gate 160 and the nanosheet, that is, the high-k dielectric layer 150 wraps the nanosheet, as shown in FIGS. 3 and 4. A material of the high-k dielectric layer 150 may comprise one or more of: HfO₂, HfSiOₓ, HfON, HfSION, HfAlOₓ, HfLaOₓ, Al₂O₃, ZrO₂, ZrSiOₓ, Ta₂O₅, and La₂O₃.

In an embodiment, the 3D stacked DRAM further comprises second sidewalls 205, isolation layers 207, a first dielectric layer 170, a second dielectric layer 180, a ground electrode 310, a word-line electrode 320, and a bit-line electrode 330.

The second sidewalls 205 are disposed on a side of the storage structure away from the substrate 110, and the gate 160 is disposed between the second sidewalls 205. The isolation layers 207 are disposed on a side of the source 131 or the drain 132 away from the substrate 110, and the second sidewalls 205 and the gate 160 are disposed between the isolation layers 207.

The first dielectric layer 170 covers the isolation layers 207, the second sidewalls 205, and the gate 160. The second dielectric layer 180 is configured to isolate different storage structures. The ground electrode 310 and the bit-line electrode 330 are disposed in the second dielectric layer 180. The ground electrode 310 is configured to connect the common source electrode 210, so that the common source electrode 210 receives the ground potential via the ground electrode 310. The bit-line electrode 330 is configured to connect the drain electrode 220, so that the drain electrode 220 is connected to the bit line through the bit-line electrode 330. The word-line electrode(s) 320 is disposed in the first dielectric layer 170 and the second dielectric layer 180 and is configured to connect the gate 160, so that the gate 160 is connected the word line(s) through the word-line electrode(s) 320.

In practice, a quantity of word-line electrodes 320 may be equal to a quantity of storage structures, each of which comprises the multiple vertically stacked nanosheets. Thus, the multiple nanosheets in the same storage structure may serve as memory cells in a same row of the array. A quantity of the bit-line electrodes 330 may be equal to a quantity of nanosheets in the storage structure, such that that each memory cell is provided with one bit-line electrode 330. Hence, there are a large quantity of bit-line electrodes 330 in the 3D stacked DRAM, and leading the bit lines out would occupy a large space. Herein some nanosheets may be led out to connect a bit line through the same bit-line electrode 330. In an embodiment, nanosheets that are in different storage structures but have the same length are electrically connected to the same bit-line electrode 330. Such structure is equivalent to connecting the memory cells in a same column of the array to a same bit line. In such case, the quantity of the bit-line electrodes 330 may be equal to the quantity of nanosheets in the storage structure. That is, a quantity of the bit lines is equal to a quantity of memory cells and is also equal to the quantity of nanosheets.

Materials of the first dielectric layer 170 and the second dielectric layer 180 may be insulating material. For example, the first dielectric layer 170 and the second dielectric layer 180 each may be made of oxide, nitride, high-k dielectric, low-k dielectric, amorphous carbon, or polymer.

In an embodiment, along a direction perpendicular to the substrate 110, a dimension of each nanosheet serving as a memory unit ranges from 1 nm to 50 nm, and a space between adjacent nanosheets ranges from 5 nm to 100 nm. Along direction XX, i.e., along the direction parallel with the extension direction of the fin(s), the length of the nanosheet ranges from 1 nm to 100 nm. Along direction YY, i.e., along the direction parallel with the extension direction of the gate, a length of the gate 160 ranges from 5 nm to 1000 nm.

In an embodiment, there are multiple storage structures, which improves integration density of the 3D stacked DRAM. The gate 160 surrounding each storage structure is connected to a respective word line. In an embodiment, as shown in FIG. 3, the storage structure comprises a first storage structure and a second storage structure, the gate 160 comprises a first gate and a second gate, and the word line comprises a first word line and a second word line. The first word line and the second word line are connected to different word-line electrodes 320, respectively.

The first gate may be isolated from the second gate via a dielectric material, for example, via the second dielectric layer 180. The first gate surrounds each nanosheets in the first storage structure and is connected to the word-line electrode 320 corresponding to the first word line. Thereby, the first gate is lead out to connect the first word line. The second gate surrounds each nanosheet in the second storage structure and is connected to the word-line electrode 320 corresponding to the second word line. Thereby, the second gate is lead out to connect the second word line. Thereby, an array of 2T0C memory cells can be formed on a basis of the mutually isolated storage structures and the gates surrounding theses storage structures. The two storage structures are led out to connect of different word lines via the two separate gates.

Herein the 3D stacked DRAM comprising the substrate, the source, the drain, the storage structure, the common source electrode, the drain electrodes, and the gate is provided. The source, the drain, and the storage structure are disposed on the side of the substrate, and the storage structure is located between the source and the drain. The storage structure comprises the stack of nanosheets, and each nanosheet extends from the source to the drain. That is, each nanosheet may serve as a memory cell for data storage. The common source electrode runs through the source to contact each nanosheet, and the common source electrode is grounded to connect each nanosheet to ground electrically, i.e., to connect the memory cell and the ground. The portion of the nanosheets that is located at the drain is shaped into the stair structure. Each drain electrode runs into the drain to connect the respective nanosheet in the stair structure, and the drain electrodes are configured to connect the bit lines for the 3D stacked DRAM, such that the nanosheets and the bit lines are electrically connected. The gate surrounds each nanosheet and is configured to connect the word line(s) for the 3D stacked DRAM, such that the nanosheets and the word line(s) are electrically connected. That is, each nanosheet is connected to the word line(s) via the gate, is grounded via the source, and is connected to the corresponding bit line via the drain to achieve data storage. Such architecture in combination with vertical stacking of memory cells improves integration density of memory cells greatly. Thereby, an array of three-dimensionally stacked 1T memory cells is formed through the vertical stacking of memory cells, gate-all-around structure of each memory cell, and the stair structure for connecting the drain in each memory cell. High-density data storage can be achieved.

On a basis of the foregoing 3D stacked DRAMs, a method for manufacturing a 3D stacked DRAM is further provided according to an embodiment of the present disclosure. Hereinafter a principle of operations is described in detail in conjunction with the drawings.

Reference is made to FIG. 5B, which is a schematic flow chart of a method for manufacturing a 3D stacked DRAM according to an embodiment of the present disclosure.

Herein the method comprises following steps S101 to S106.

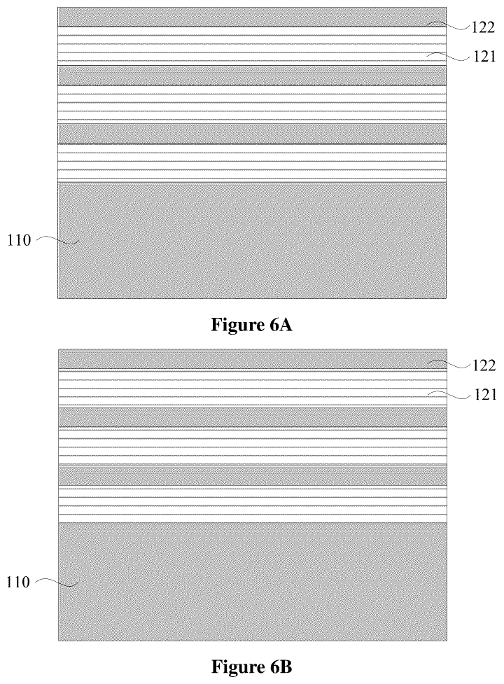

In step S101, a substrate 110 is provided, where a stacked structure comprising first semiconductor layers 121 and second semiconductor layers 122 that are alternately arranged is formed on a side of the substrate 110. Reference is made to FIG. 6A and FIG. 6B.

In an embodiment, the substrate 110 may be a semiconductor substrate, such as a bulk silicon substrate. The substrate 110 may be doped to obtain a p-doped semiconductor substrate or an n-doped semiconductor substrate, such as a p-doped silicon substrate or an n-doped silicon substrate.

As an example, dopants are injected into the bulk silicon substrate, and then the bulk silicon substrate is annealed to obtain a highly doped well region which reaches a required well depth. Dopants in the substrate 110 may have different polarities for different device types. For p-type semiconductor devices, the highly doped well region is an n-well, and the dopants are ions serving as n-type dopants, such as phosphorus ions. For n-type semiconductor devices, the highly doped well region is a p-well, and the dopants are ions serving as p-type dopants, such as boron ions.

Herein the stacked structure comprising the first semiconductor layers 121 and the second semiconductor layers 122 that are alternately arranged may be formed on the side of the substrate 110, as shown in FIGS. 6A and 6B. FIG. 6A is a schematic structural diagram of a cross section along direction XX of the semiconductor device as shown in FIG. 2 according to an embodiment of the present disclosure. FIG. 6B is a schematic structural diagram of another cross section along direction YY of the semiconductor device as shown in FIG. 2 according to an embodiment of the present disclosure. Direction YY refers to a direction parallel with an extension direction of the gate, and the XX direction refers to direction parallel with an extension direction of fin(s).

The first semiconductor layer 121 and the second semiconductor layer 122 may be formed through epitaxy.

A material of the first semiconductor layer 121 may be identical to a material the second semiconductor layer 122 for a certain type of device. For example, the material of the first semiconductor layer 121 may be silicon or germanium, and the material of the second semiconductor layer 122 may also be silicon or germanium. The material of the first semiconductor layer 121 may be different from that of the second semiconductor layer 122 for another type of device. As an example, in a p-type semiconductor device, the material of the first semiconductor layer 121 may be silicon, and the material of the second semiconductor layer 122 may be silicon-germanium. As another example, in an n-type semiconductor device, the material of the first semiconductor layer 121 may be silicon-germanium, and the material of the second semiconductor layer 122 may be silicon.

In practice, silicon oxide may be formed on the substrate 110. Thus, the stacked structure may be formed after removing the silicon oxide on the substrate 110 and rinsing the substrate 110.

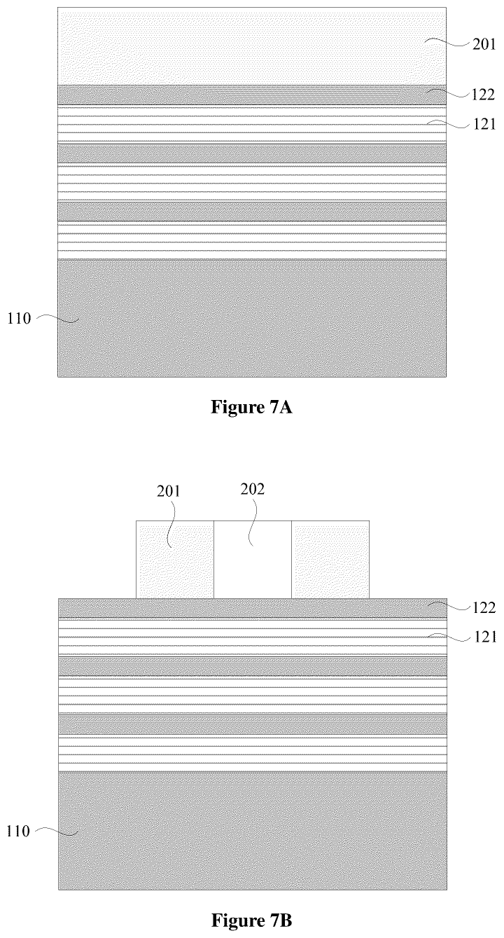

In an embodiment, the first sidewall 201 may be formed through sidewall transfer. Reference is made to FIGS. 7A and 7B. The first sidewall 201 may formed through self-aligned sidewall transfer, and a material of the first sidewall 201 may be silicon nitride or silicon oxide. The first sidewall 201 may be formed through following steps. A sacrificial layer 202 covering the stacked structure is formed. A material of the sacrificial layer 202 may be polysilicon or amorphous silicon. A portion of the sacrificial layer 202 is removed through photolithography, which comprises patterning and etching. Then, silicon nitride or silicon oxide is deposited. Afterwards, the remaining sacrificial layer 202 is removed through anisotropic etching, after which only the first sidewall(s) 201 remains on the stacked structure. The first sidewall(s) 201 serves as a hard mask in subsequent photolithography for forming fin(s).

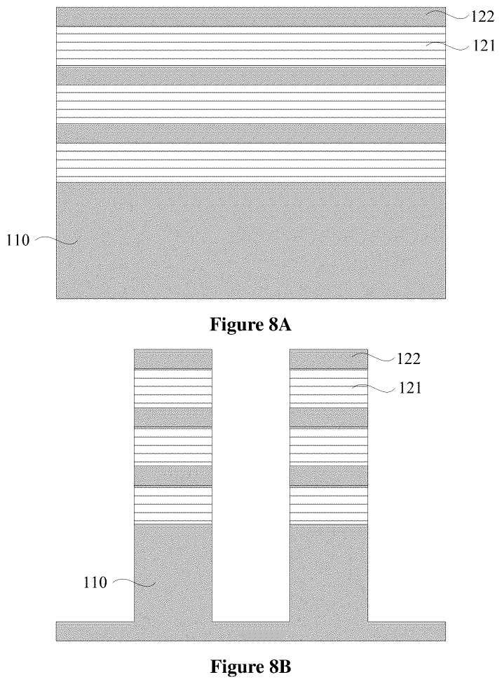

In an embodiment, the stacked structure is etched to form multiple fins that are periodically arranged. Reference is made to FIGS. 8A and 8B. The first sidewall 201 serves as a mask during the etching, and hence each formed fin comprises a part of the stacked structure. An upper part of each fin is a channel region 103 that origins from the stacked structure, and a lower part of each fin origins from the substrate 110, as shown in FIG. 8B. That is, each fin comprises not only a stacked structure, but also single crystal silicon extends into the substrate 110. The etching may be dry etching or wet etching. In an embodiment, reactive ion etching may be utilized. The fins are configured to provide nanosheets in the 3D stacked DRAM. Although only two fins are depicted in FIG. 8B, it is appreciated any appropriate number of fins, each of which has any appropriate shape, may be formed in practice.

In practice, forming the two fins comprises etching the stacked structure and the substrate 110 to form a first fin and a second fin in a same process. The first sidewall 201 may be removed after the first fin and the second fin are formed.

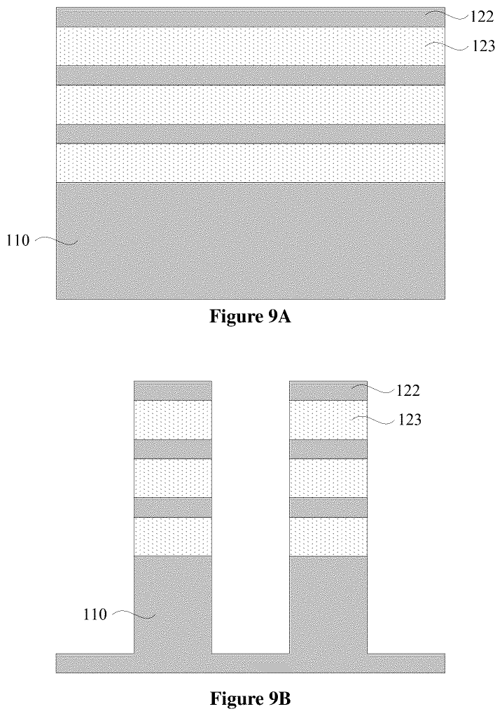

In step S102, the first semiconductor layers 121 are oxidized to obtain a new stacked structure in which the isolation layers 123 and the second semiconductor layers 122 are alternately arranged. Reference is made to FIG. 9A and FIG. 9B.

In an embodiment, the first semiconductor layers 121 may be oxidized to obtain isolation layers 123. The isolation layers 123 and the second semiconductor layers 122 are alternately stacked to form the new stacked structure, as shown in FIGS. 9A and 9B.

In an embodiment, the first semiconductor layers 121 may be oxidized through selective oxidation. After the oxidization, the isolation layers 123 are configured to isolate the second semiconductor layers 122.

In an embodiment, a material of the first semiconductor layers 121 is silicon-germanium, and a material of the second semiconductor layer 122 is silicon. The silicon-germanium is oxidized through selective oxidation to obtain the isolation layers 123.

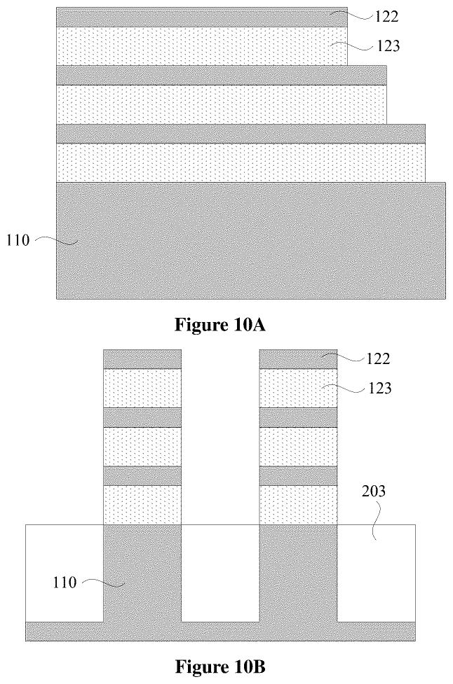

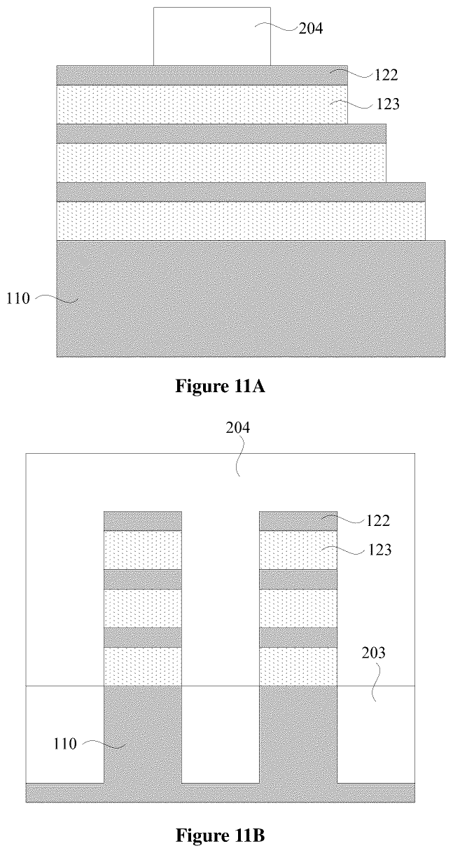

In step S103, a side portion of the new stacked structure is shaped through photolithography into a stair structure. Reference is made to FIG. 10A and FIG. 10B.

Herein the stair structure configured for connecting bit lines is fabricated from the side portion of the stacked structure through the photolithography, as shown in FIGS. 10A and 10B.

A process of this step may be as follows. A photoresist layer is formed on the new stacked structure. Then, the photoresist layer is trimmed. The new stacked structure is etched with the trimmed photoresist layer as a mask to form one step in the stair structure. A depth of the etching is equal to a thickness of one period of the new stacked structure, i.e., a thickness of one isolation layer 123 plus one second semiconductor layer 122. Afterwards, the photoresist layer is trimmed again, and the stacked structure is etched again with the newly trimmed photoresist layer as a mask to form the next step in the stair structure. Such trimming and etching are repeated until the stair structure is formed, and lengths of the steps along a direction from the source 131 toward the drain 132 increase sequentially. That is, the stair structure in which lengths of the nanosheets along the XX direction increase sequentially is formed. Afterwards, the photoresist layer is removed.

That is, the stair structure may comprise single steps of which the lengths along a direction parallel with a surface of the substrate 110 increase sequentially. Such single-step structure may be formed through trimming the photoresist layer and etching the stacked structure alternately.

In an embodiment, the stair structure has two steps and is formed through following etching process. The photoresist layer is trimmed, and then the stacked structure is etched with the trimmed photoresist layer as the mask to form a first step, where the depth of the etching is equal to the thickness of one period of the stacked structure. Afterwards, the photoresist layer is trimmed again, and then the stacked structure is etched again with the newly trimmed photoresist layer as the mask to form a second step. The photoresist layer is then removed.

The stacked structure may be etched through dry etching, such as reactive ion etching (RIE), or wet etching. The depth of the etching is the thickness of one period of the stacked structure. A rate of the etching rate may be obtained based on the depth of the etching. A location and a width of the etching are determined according to predetermined parameters of the stair structure. The parameters of the stair structure may be determined based on a size of the drain electrode 220 that would be formed in a subsequent step.

In an embodiment, shallow trench isolation (STI) 203 may be formed between different fins. Reference is made to FIGS. 10A and 10B. The shallow trench isolation 203 adjacent to the fins may be formed through following steps. A dielectric insulating material is deposited and then planarized through, for example, chemical-mechanical planarization. Then, the dielectric insulating material is etched to expose the 3D fins. A surface of the shallow trench isolation 203 away from the substrate 110 may be flush with an interface between the stacked structure and the substrate 110 in the fins, or it may be higher or lower than such interface. The shallow trench isolation 203 may be made of an appropriate dielectric material, such as silicon dioxide or silicon nitride. The shallow trench isolation 203 is configured to separate channels in adjacent fins.

In an embodiment, a dummy gate stack is formed on the exposed fin(s), and the dummy gate stack extends in a direction perpendicular to the extension direction of the fin(s), i.e., in direction YY. Reference is made to FIGS. 11A and 11B. The dummy gate stack may be a multi-layer structure comprising a gate insulating dielectric layer (not depicted), a dummy gate 204, and a hard mask layer (not depicted). The dummy gate stack may be formed through, for example, thermal oxidation, chemical vapor deposition, or sputtering. The dummy gate stack is astride of the stack structure in the upper part of the fin. Multiple dummy gates may be periodically arranged along the extension direction of the fin(s). A material of the dummy gate 204 may be polysilicon or amorphous silicon. A material of the hard mask layer may be oxide, carbide, organic matter, or the like.

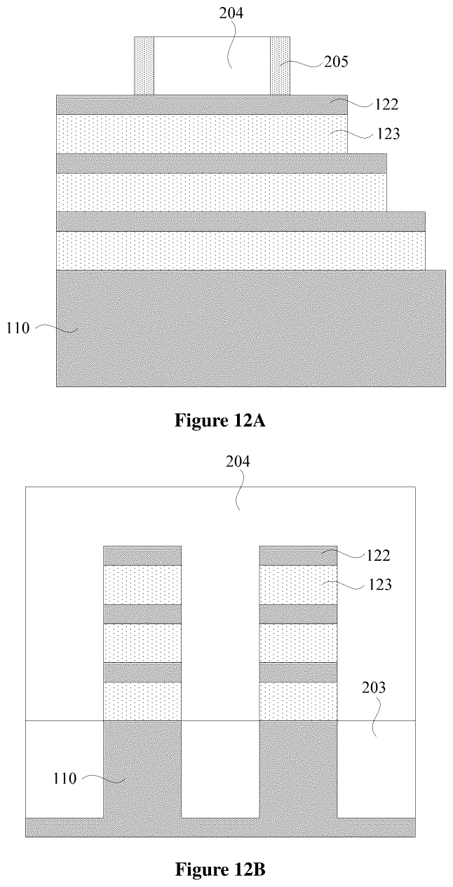

In an embodiment, the second sidewalls 205 may be disposed on twos sides of the dummy gate stack along the extension direction of the fin(s), i.e., along the XX direction. Reference is made to FIG. 12A and FIG. 12B. The second sidewalls 205 on the two sides are identical in thickness. A material of the second sidewall 205 may be a dielectric material for isolation, such as silicon nitride or doped silicon oxide.

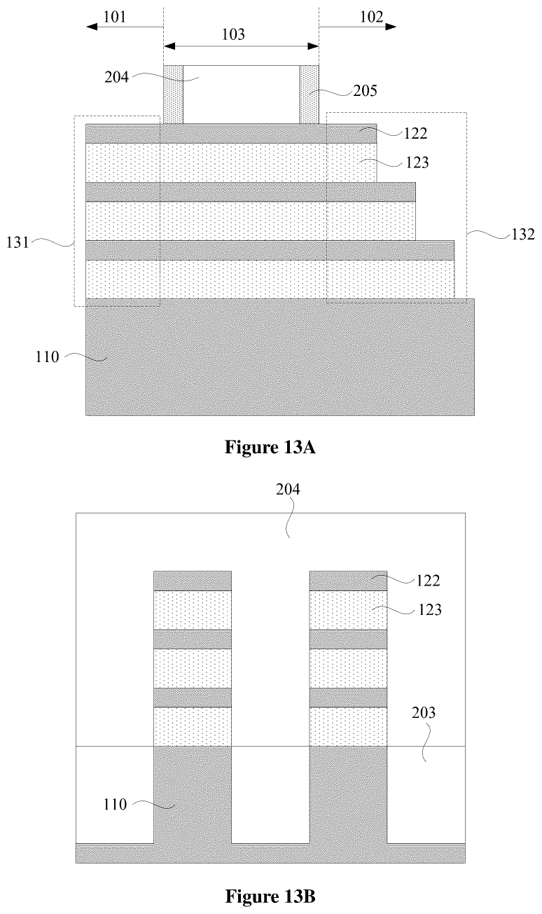

In step S104, two side portions of the new stacked structure is doped to form a source 131 and a drain 132, respectively. Reference is made to FIG. 13A and FIG. 13B.

In an embodiment, after the dummy gate 204 and the second sidewalls 205 have been formed, each fin is doped to form a source region 101 and a drain region 102, and the dummy gate 204 and the second sidewalls 205 serve as a mask during the doping. In the source region 101, the stacked structure is doped as the source 131. In the drain region 102, the stacked structure is doped as the drain 132. The drain 132 comprises the stair structure. A portion of the new stacked structure between the source region 101 and the drain region 102 serves as a channel region 103. The stacked structure in the channel region 103 is not doped due to being covered by the dummy gate 204 and the second sidewalls 205, and hence a channel structure can be formed. As shown in FIG. 13A, the channel structure is located between the source 131 and the drain 132.

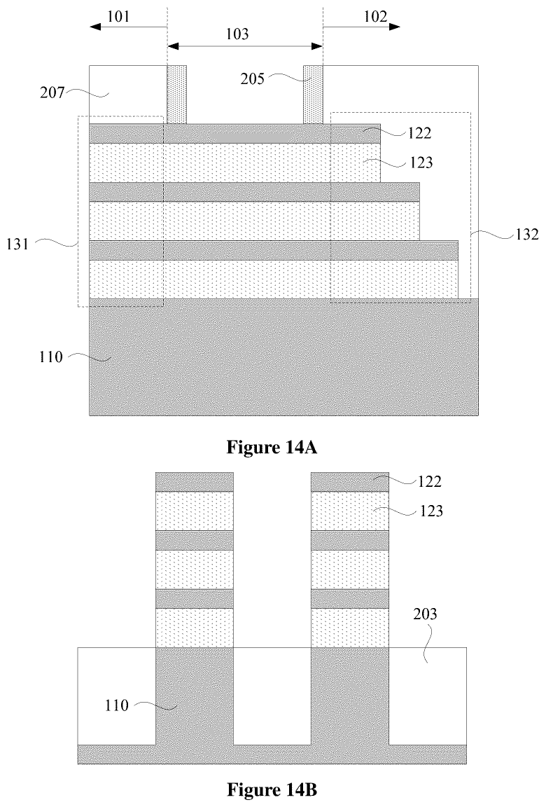

In an embodiment, an isolation layer 207 may be deposited at a surface of the dummy gate 204, a surface of the source 131, and a surface of the drain 132. The isolation layer 207 is configured to prevent a short circuit in interconnections, which is formed in a subsequent step, between the dummy gate 204 and the source 131 and between the dummy gate 204 the drain 132. The isolation layer 207 may be planarized through chemical mechanical polishing. Then, the dummy gate 204 is removed. Reference is made to FIGS. 14A and 14B. The dummy gate 204 made of polysilicon or amorphous silicon is processed through selective etching or corrosion, that is, the dummy gate 204 is removed.

In step S105, the isolation layers 123 in the channel structure are replaced with the gate 160 which surrounds each second semiconductor layer 122, where the stacked second semiconductor layers 122 serve as a storage structure.

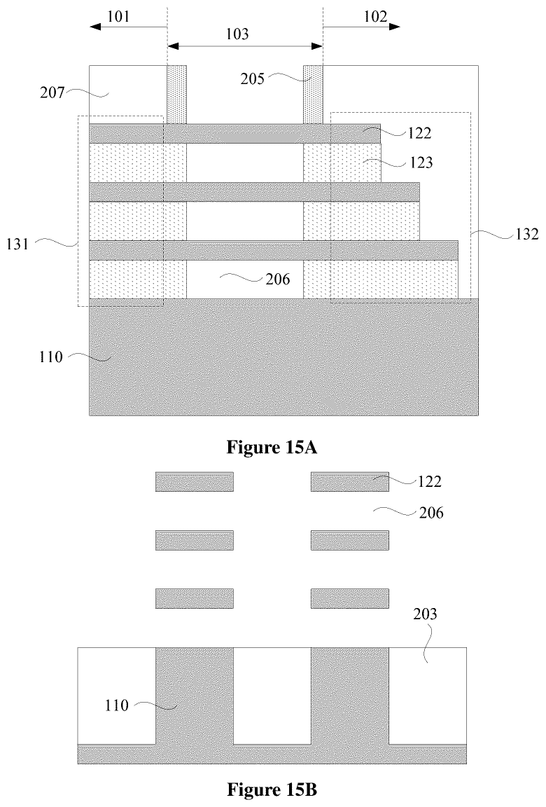

In an embodiment, the isolation layers 123 in the channel region 103 is removed. That is, the nanosheets serving as a channel are released. Thereby, multiple gaps 206 are formed and are to be filled among the second semiconductor layers 122. Reference is made to FIG. 15A and FIG. 15B.

In an embodiment, the isolation layers 123 in the channel structure of the channel region 103 may be removed through selective etching to release the nanosheet channel. That is, the exposed channel structure of the fin(s) is processed to remove each isolation layer 123, and the isolation layers 123 serve as sacrificial layers for releasing the nanosheets formed by the second semiconductor layers 122.

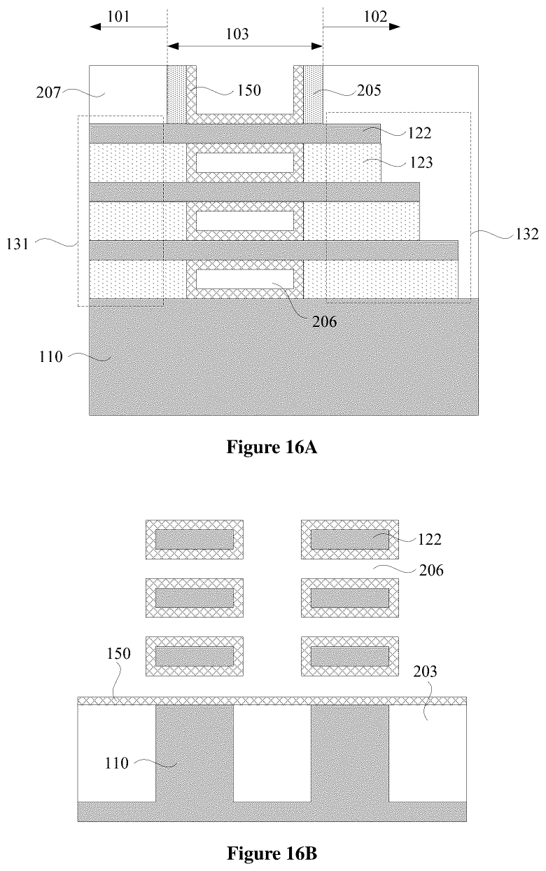

In an embodiment, after removing the isolation layers 123 located in the channel region 103, a high-k dielectric layer 150 is formed on a surface of each second semiconductor layer 122, and the high-k dielectric layer 150 surrounds each second semiconductor layer 122. Reference is made to FIG. 16A and FIG. 16B. A material of the high-k dielectric layer 150 may be any one or any combination of: HfO₂, HfSiOₓ, HON, HfSiON, HfAlOₓ, HfLaOₓ, Al₂O₃, ZrO₂, ZrSiOₓ, Ta₂O₅, or La₂O₃.

In practice, the high-k dielectric layer 150 may comprise an interface oxide layer (IL) (not depicted).

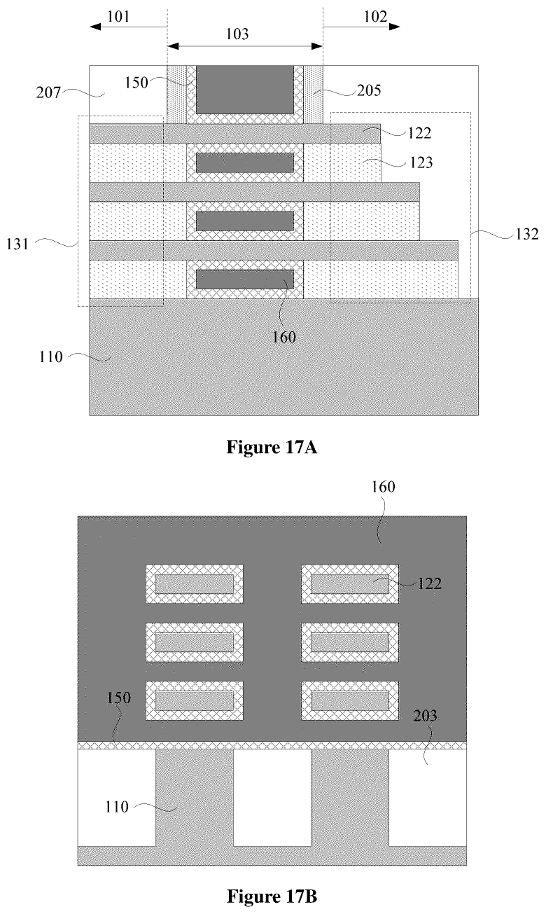

After the nanosheet channel is released, the multiple gaps 206 are formed among multiple second semiconductor layers 122. In an embodiment, the gaps 206 are filled with the gate 160. Thereby, the gate 160 surrounds each second semiconductor layer 122 to form a gate-all-around structure. A stack of multiple second semiconductor layers 122 may serve as the storage structure, i.e., memory cells of the 3D stacked DRAM. Reference is made to FIG. 17A and FIG. 17B.

In practice, the gate 160 may comprise another multi-layer structure (not depicted) comprising, for example, as a diffusion barrier layer, a work function layer, and/or a conductive filling layer.

In practice, besides the gaps 206, the gate 160 further covers the isolation layer 207 and occupies a space formed through removing the dummy gate 204. The gate 160 covering the isolation layer 207 may be planarized through chemical-mechanical polishing.

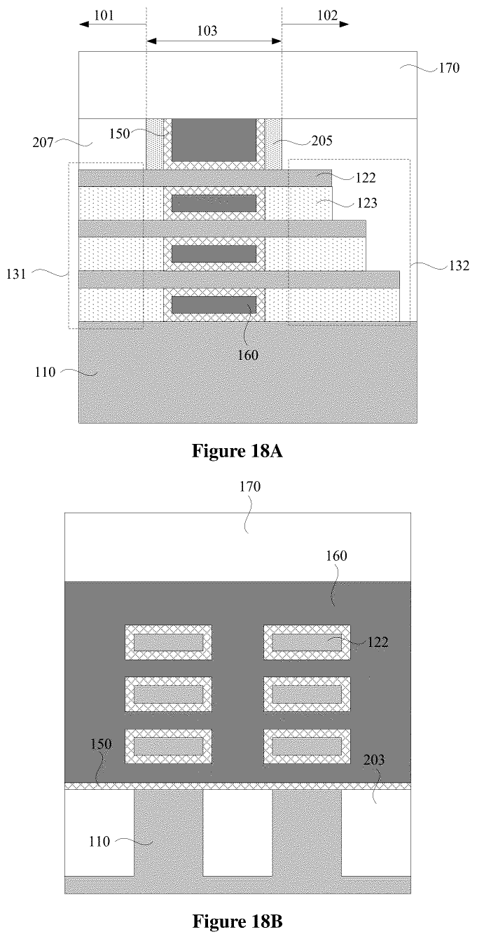

In an embodiment, after the gate 160 is formed, a dielectric material may be deposited on a surface the 3D stacked DRAM opposite to a side of the substrate 110 to form a first dielectric layer 170. Reference is made to FIGS. 18A and 18B.

In step S106, a common source electrode 210 running through the source 131 is formed, and multiple drain electrodes 220 running into the drain 132 are formed.

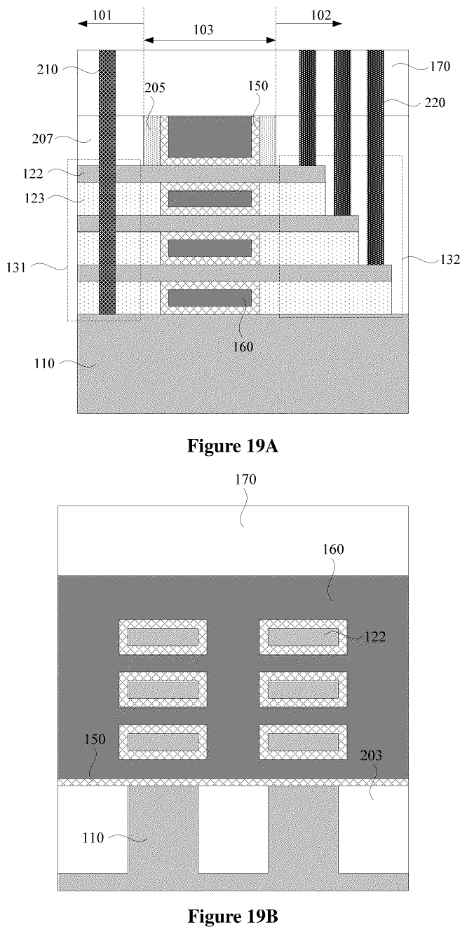

In an embodiment, the first dielectric layer 170 and the source 131 are etched to form a contacting hole reaching the surface of the substrate 110, and the common source electrode 210 running through the source 131 is formed through depositing a metallic material in the contacting hole. The common source electrode 210 is in contact with each second semiconductor layer 122, so that each memory cell utilizes the common source electrode 210 to interconnect with the word line. The common source electrode 210 is connected to the ground potential. Reference is made to FIG. 19A and FIG. 19B. As an example, the metallic material is tungsten.

In an embodiment, the first dielectric layer 170 and the drain 132 are etched to form multiple contacting holes reaching surfaces of the steps, respectively, in the stair structure, and the multiple drain electrodes 220 are formed through depositing a metallic material in the multiple contacting holes. Each drain electrode 220 is in contact with a respective second semiconductor layer 122 in the stair structure, so that each memory cell utilizes the corresponding drain electrode 220 to interconnected with the bit line. Reference is made to FIG. 19A and FIG. 19B.

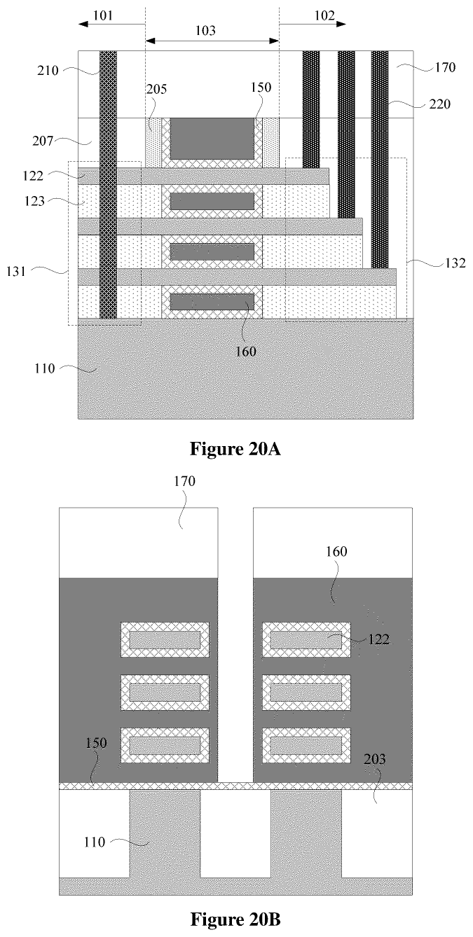

In an embodiment, the gate 160 may be etched to isolated storage structures located in different fins. Reference is made to FIGS. 20A and 20B. The first fin has a first storage structure, and the second fin has a second storage structure. The gate 160 is etched along a direction, which is perpendicular to a surface of the substrate 110 and perpendicular to a line connecting the source 131 and the drain 132, i.e., direction XX, to form a first gate and a second gate. The first gate surrounds each second semiconductor layer 122 in the first storage structure and may be connected to a first word line in a subsequent step. The second gate surrounds each second semiconductor layer 122 in the second storage structure and may be connected to a second word line in a subsequent step.

In an embodiment, a dielectric material is filled in a gap between the first gate and the second gate for isolation. The dielectric material may be deposited to form the second dielectric layer 180 as shown in FIG. 4. The first dielectric layer 170 and the second dielectric layer 180 may be etched to form a contacting hole reaching a surface of the gate 160, and a word-line electrode 320 is formed through depositing a metallic material in the contacting hole. The word-line electrode 320 are configured to connect the gate 160, so that the gate 160 is interconnected with the world line via the word-line electrodes.

In an embodiment, the second dielectric layer 180 are etched to form contact holes reaching the surface of the first dielectric layer 170, and a metallic material is deposited in the contact holes to from a ground electrode 310, which connects the common source electrode 210, and bit-line electrodes 330, which connect the drain electrodes 220. Reference is made to FIG. 3.

The embodiments of the present disclosure are described in a progressive manner, and each embodiment places emphasis on the difference from other embodiments. Therefore, one embodiment may refer to other embodiments for the same or similar parts. Since the methods disclosed in the embodiments correspond to the apparatuses disclosed in the embodiments, the description of the methods is simple, and reference may be made to the relevant part of the apparatuses. The foregoing embodiments are only illustrative, and those skilled in the art can understand and implement them without exerting creative efforts.

The foregoing embodiments are only preferable embodiments of the present disclosure and are not intended for limiting the present disclosure. Those skilled in the art can make various changes and modifications to the technical solutions of the present disclosure, or derive some equivalent embodiments, on a basis of the schemes and technical content discloses herein, without departing from a scope of technical solutions of the present disclosure. All modifications, equivalent variations, and improvements made on a basis of the technical essence of the present disclosure without departing from content of the technical solutions of the present disclosure shall fall within the protection scope of the present disclosure.

1. A three-dimensional (3D) stacked dynamic random-access memory (DRAM), comprising:
a substrate;
a source, a drain, and a storage structure, which are disposed on a side of the substrate, wherein the storage structure comprises a portion of a stack of nanosheets which is located between the source and the drain, each of the nanosheets extends from the source to the drain, and another portion of the nanosheets which extends into the drain is shaped into a stair structure;
a common source electrode running through the source, wherein the common source electrode is in contact with each of the nanosheets and is grounded;
drain electrodes running into the drain, wherein each of the drain electrodes is in contact with a respective one of the nanosheets that forms a step of the stair structure, and the drain electrodes are configured to connect bit lines for the 3D stacked DRAM; and
a gate surrounding each of the nanosheets, wherein the gate is configured to connect one or more word lines for the 3D stacked DRAM.

2. The 3D stacked DRAM according to claim 1, wherein:
the storage structure comprises a first storage structure and a second storage structure, the gate comprises a first gate and a second gate, and the one or more word lines comprise a first word line and a second word line;
the first gate and the second gate are isolated by a dielectric material;
the first gate surrounds each of the nanosheets in the first storage structure and is configured to connect the first word line; and
the second gate surrounds each of the nanosheets in the second storage structure and is configured to connect the second word line.

3. The 3D stacked DRAM according to claim 1, wherein lengths of the nanosheets gradually increase in a direction pointing from the storage structure to the substrate.

4. The 3D stacked DRAM according to claim 3, wherein the source and the drain are asymmetric to each other in structure.

5. The 3D stacked DRAM according to claim 1, wherein a quantity of the bit lines is identical to a quantity of the nanosheet.

6. A method for manufacturing a three-dimensional (3D) stacked dynamic random-access memory (DRAM), comprising:
providing a substrate, wherein a first stacked structure in which first semiconductor layers and second semiconductor layers are alternately arranged is formed on a side of a substrate;
oxidizing the first semiconductor layers to obtain a second stacked structure in which isolation layers and the second semiconductor layers are alternately arranged;
shaping a side portion of the second stacked structure through photolithography into a stair structure;
doping two side portions of the second stacked structure to form a source and a drain, respectively, wherein the drain comprises the stair structure, and the second stacked structure between the source and the drain serves as a channel structure;
replacing the isolation layers in the channel structure with a gate, wherein the gate surrounds each of the second semiconductor layers in the channel structure, the stacked second semiconductor layers in the channel structure serve as a storage structure, and the gate is configured to connect one or more word lines for the 3D stacked DRAM; and
forming a common source electrode which runs through the source, and forming drain electrodes which run into the drain, wherein the common source electrode is in contact with each of the second semiconductor layers in the source and is grounded, each drain electrode is in contact with a respective one of the second semiconductor layers in the stair structure, and the drain electrodes are configured to connect bit lines for the 3D stacked DRAM.

7. The method according to claim 6, wherein oxidizing the first semiconductor layers to obtain the second stacked structure comprises:
oxidizing the first semiconductor layers through selective oxidation.

8. The method according to claim 6, wherein shaping the side portion of the second stacked structure through the photolithography into the stair structure comprises:
forming a photoresist layer on the second stacked structure;
repeating operation cycles to form the stair structure, wherein lengths of steps of the stair structure increase gradually along a direction pointing from the second stacked structure to the substrate, and each of the operation cycles comprises:
trimming the photoresist layer, and
etching the second stacked structure with the trimmed photoresist layer as a mask to form one step in the stair structure, wherein a depth of the etching is equal to a thickness of a period of the second stacked structure, and
removing the photoresist layer.

9. The method according to claim 6, wherein:
before oxidizing the first semiconductor layers to obtain the second stacked structure, the method further comprises:
etching the first stacked structure and the substrate to form a first fin and a second fin, wherein the storage structure comprises a first storage structure and a second storage structure, the first storage structure is fabricated from the first fin, and the second storage structure is fabricated from the second fin, the gate comprises a first gate and a second gate, and the word line comprises a first word line and a second word line;
the method further comprises:
etching the gate along a direction perpendicular to the substrate to form the first gate and the second gate, wherein:
the first gate surrounds each of the second semiconductor layers in the first storage structure, and the first gate is configured to connect the first word line; and
the second gate surrounds each of the second semiconductor layers in the second storage structure, and the second gate is configured to connect the second word line; and
filling a gap between the first gate and the second gate with a dielectric material for isolation.

10. The method according to claim 6, wherein replacing the isolation layers in the channel structure with the gate comprises:
removing the isolation layers in the channel structure to form a plurality of gaps among the second semiconductor layers; and
filling the plurality of gaps with the gate.
